(19) United States
(12) Patent Application Publication
(10) Pub. No.: US 2024/0186347 A1
(43) Pub. Date: Jun. 6, 2024

(54) IMAGE SENSING DEVICE AND METHOD FOR MANUFACTURING THE SAME

(71) Applicant: SK hynix Inc., Icheon-si (KR)

(72) Inventor: Won Jin KIM, Icheon-si (KR)

(21) Appl. No.: 18/365,423

(22) Filed: Aug. 4, 2023

(30) Foreign Application Priority Data
Dec. 2, 2022 (KR) 10-2022-0166544

(51) Int. Cl. H01L 27/146

(52) U.S. Cl. CPC H01L 27/14621; H01L 27/14623; H01L 27/14627; H01L 27/14645; H01L 27/14685

(57) ABSTRACT

An image sensing device includes a plurality of first color filters configured to transmit light corresponding to a first color, a plurality of second color filters configured to transmit light corresponding to a second color, a plurality of third color filters configured to transmit light corresponding to a third color, a plurality of fourth color filters configured to transmit light corresponding to a fourth color, and a grid structure disposed between the first to fourth color filters and structured to block light from one color filter to another color filter. Some color filters from among the first to fourth color filters are formed to have a lower height than the grid structure, and the remaining color filters are formed to have a higher height than the grid structure.

### CROSS-REFERENCE TO RELATED APPLICATION

This patent document claims the priority and benefits of Korean patent application No. 10-2022-0166544, filed on Dec. 2, 2022, which is incorporated by reference in its entirety as part of the disclosure of this patent document.

### TECHNICAL FIELD

The technology and implementations disclosed in this patent document generally relate to an image sensing device and a method for manufacturing the same.

### BACKGROUND

An image sensor is used in electronic devices to convert optical images into electrical signals. With the recent development of automotive, medical, computer and communication industries, the demand for highly integrated, higher-performance image sensors has been rapidly increasing in various electronic devices such as digital cameras, camcorders, personal communication systems (PCSs), video game consoles, surveillance cameras, medical micro-cameras, robots, etc.

### SUMMARY

The disclosed technology can be implemented in some embodiments to prevent an image sensing device including white color filters from color mixing.

In some embodiments of the disclosed technology, an image sensing device may include a plurality of first color filters configured to transmit light corresponding to a first color, a plurality of second color filters configured to transmit light corresponding to a second color, a plurality of third color filters configured to transmit light corresponding to a third color, a plurality of fourth color filters configured to transmit light corresponding to a fourth color, and a grid structure disposed between the first to fourth color filters and structured to block light from one color filter to another color filter, wherein one or more color filters of the first to fourth color filters are formed to have a lower height than the grid structure, and one or more remaining color filters other than the one or more color filters are formed to have a higher height than the grid structure.

In some embodiments of the disclosed technology, a method for manufacturing an image sensing device may include forming a grid structure over a semiconductor substrate, and sequentially forming first, second, third, and fourth color filters, configured to transmit light corresponding to light of first, second, third, and fourth colors, respectively, in different spaces from among spaces defined by the grid structure, wherein one or more color filters of the first to fourth color filters are formed to have a lower height than the grid structure, and one or more remaining color filters other than the one or more color filters are formed to have a higher height than the grid structure.

In some embodiments of the disclosed technology, an image sensing device may include a plurality of first color filters configured to transmit light corresponding to a first color, a plurality of second color filters configured to transmit light corresponding to a second color, a plurality of third color filters configured to transmit light corresponding to a third color, a plurality of fourth color filters configured to transmit light corresponding to a fourth color, and a grid structure disposed between the first to fourth color filters and structured to block light from one color filter to another color filter, wherein some color filters from among the first to fourth color filters are formed to have a lower height than the grid structure, and the remaining color filters other than the some color filters are formed to have a higher height than the grid structure.

In some embodiments of the disclosed technology, a method for manufacturing an image sensing device may include forming a grid structure over a semiconductor substrate, and sequentially forming first, second, third, and fourth color filters, configured to transmit light corresponding to light of first, second, third, and fourth colors, respectively, in different spaces from among spaces defined by the grid structure, wherein some color filters from among the first to fourth color filters are formed to have a lower height than the grid structure, and the remaining color filters other than the some color filters are formed to have a higher height than the grid structure.

In some embodiments of the disclosed technology, an image sensing device may include a plurality of photoelectric conversion regions structured to detect incident light and generate photocharge corresponding to an intensity of the incident light, a plurality of first color filters disposed over the plurality of photoelectric conversion regions and configured to transmit light corresponding to a first color, a plurality of second color filters disposed over the plurality of photoelectric conversion regions and configured to transmit light corresponding to a second color, a plurality of third color filters disposed over the plurality of photoelectric conversion regions and configured to transmit light corresponding to a third color, a plurality of fourth color filters disposed over the plurality of photoelectric conversion regions and configured to transmit light corresponding to a fourth color, and a grid structure disposed between the first to fourth color filters and structured to block light from one color filter to another color filter, wherein at least one of the first to fourth color filters is formed to have a lower height than the grid structure, and at least one remaining color filter other than the at least one of the first to fourth color filters is formed to have a higher height than the grid structure.

In some embodiments of the disclosed technology, a method for manufacturing an image sensing device may include forming a grid structure over a semiconductor substrate that includes a plurality of photoelectric conversion regions structured to detect incident light and generate photocharge corresponding to an intensity of the incident light, and sequentially forming first, second, third, and fourth color filters, configured to transmit light corresponding to light of first, second, third, and fourth colors, respectively, in different spaces from among spaces defined by the grid structure, wherein at least one of the first to fourth color filters is formed to have a lower height than the grid structure, and at least one remaining color filters other than the at least one of the first to fourth color filters is formed to have a higher height than the grid structure.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

FIG. 1 is a block diagram illustrating an example of an image sensing device based on some implementations of the disclosed technology.

FIG. 2 is a schematic diagram illustrating an example structure that includes pixels arranged in a pixel array of FIG. 1 based on some implementations of the disclosed technology.

FIG. 3 is a cross-sectional view illustrating an example of the pixel array taken along the line A-A′ shown in FIG. 2 based on some implementations of the disclosed technology.

FIGS. 4A to 4F are cross-sectional views illustrating examples of methods for forming a grid structure shown in FIG. 3 based on some implementations of the disclosed technology.

### DETAILED DESCRIPTION

This patent document provides implementations and examples of an image sensing device and a method for forming the same that may be used to substantially address one or more technical or engineering issues and mitigate limitations or disadvantages encountered in some other image sensing devices. Some implementations of the disclosed technology suggest examples of a technology for preventing an image sensing device including white color filters from color mixing.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

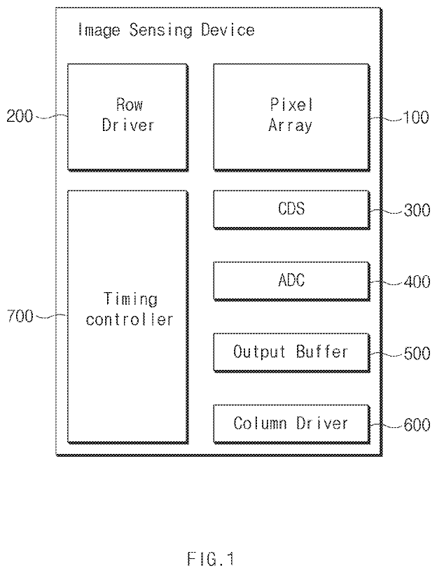

FIG. 1 is a block diagram illustrating an image sensing device based on some implementations of the disclosed technology.

Referring to FIG. 1, the image sensing device may include a pixel array 100, a row driver 200, a correlated double sampler (CDS) 300, an analog-to-digital converter (ADC) 400, an output buffer 500, a column driver 600, and a timing controller 700.

The pixel array 100 may include a plurality of unit pixels consecutively arranged in row and column directions. Each of the unit pixels may generate an electrical signal (pixel signal) in response to incident light through photoelectric conversion of incident light received from the outside. The plurality of unit pixels may include a plurality of color filters, i.e., red color filters (R), green color filters (G), blue color filters (B), and white color filters (W).

The pixel array 100 may receive driving signals (for example, a row selection signal, a reset signal, a transmission (or transfer) signal, etc.) from the row driver 200. Upon receiving the driving signal, the unit pixels may be activated to perform the operations corresponding to the row selection signal, the reset signal, and the transfer signal.

The row driver 200 may activate the pixel array 100 to perform certain operations on the unit pixels in the corresponding row based on control signals provided by controller circuitry such as the timing controller 700.

The correlated double sampler (CDS) 300 may remove undesired offset values of the unit pixels using correlated double sampling. The CDS 300 may transfer the reference signal and the pixel signal of each of the columns as a correlate double sampling (CDS) signal to the ADC 400 based on control signals from the timing controller 700.

The ADC 400 is used to convert analog CDS signals received from the CDS 300 into digital signals.

The output buffer 500 may temporarily store column-based image data provided from the ADC 400 based on control signals of the timing controller 700.

The column driver 600 may select a column of the output buffer 500 upon receiving a control signal from the timing controller 700, and sequentially output the image data, which are temporarily stored in the selected column of the output buffer 500.

The timing controller 700 may generate signals for controlling operations of the row driver 200, the ADC 400, the output buffer 500 and the column driver 600.

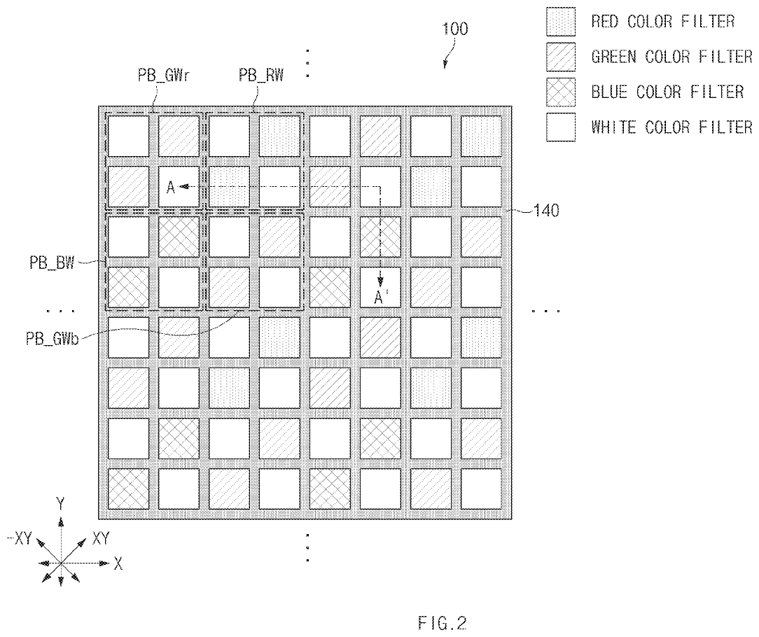

FIG. 2 is a schematic diagram illustrating an example structure that includes pixels arranged in the pixel array 100 of FIG. 1 based on some implementations of the disclosed technology.

Referring to FIG. 2, the pixel array 100 may include a plurality of sub-pixel blocks (PB_RW, PB_GWr, PB_GWb, PB_BW). The sub-pixel blocks (PB_RW, PB_GWr, PB_GWb, PB_BW) may be arranged adjacent to each other in a (2×2) array. The sub-pixel blocks (PB_RW, PB_GWr, PB_GWb, PB_BW) arranged in the (2×2) array may be consecutively arranged in X-axis and Y-axis directions.

In some implementations, each of the sub-pixel blocks (PB_RW, PB_GWr, PB_GWb, PB_BW) may include a structure in which a plurality of unit pixels is arranged adjacent to each other in an (N×N) array (where N is a natural number that is equal to or greater than 2). Each unit pixel may generate an electrical signal (pixel signal) corresponding to incident light through photoelectric conversion of the incident light. In some implementations, each unit pixel may include a photoelectric conversion region that can detect incident light and generate photocharge corresponding to an intensity of the incident light.

In some implementations, each of the sub-pixel blocks (PB_RW, PB_GWr, PB_GWb, PB_BW) may have a structure in which four unit pixels are arranged adjacent to each other in a (2×2) array. In this case, each of the sub-pixel blocks (PB_RW, PB_GWr, PB_GWb, PB_BW) may include color filters of two different colors.

In some implementations, each of the sub-pixel blocks (PB_RW, PB_GWr, PB_GWb, PB_BW) may include a white color pixel that is sensitive to the full visible spectrum including light corresponding to red, green and blue colors. For example, the sub-pixel block PB_RW may include two red color pixels and two white color pixels. The two red color pixels may be arranged adjacent to each other in a first diagonal direction (e.g., XY direction), and each of the two red color pixels may include a red color filter. The two white color pixels may be arranged adjacent to each other in a second diagonal direction (e.g., −XY direction) crossing the first diagonal direction (e.g., XY direction), and each of the two white color pixels may include a white color filter. The sub-pixel block PB_GWr may include two green color pixels and two white color pixels, and the sub-pixel block PB_GWb may include two green color pixels and two white color pixels. In this case, the two green color pixels may be arranged adjacent to each other in a first diagonal direction (XY direction), and each of the two green color pixels may include a green color filter. The two white color pixels may be arranged adjacent to each other in a second diagonal direction (e.g., −XY direction), and each of the two white color pixels may include a white color filter. The sub-pixel block PB_BW may include two blue color pixels and two white color pixels. In this case, the two blue color pixels may be arranged adjacent to each other in a first diagonal direction (e.g., XY direction), and each of the two blue color pixels may include a blue color filter. The two white color pixels may be arranged adjacent to each other in a second diagonal direction (e.g., −XY direction), and each of the two white color pixels may include a white color filter. In some implementations, the white color filter may transmit light corresponding to red, green and blue colors.

Based on the red color filter, the green color filter, and the blue color filter respectively included in the sub-pixel blocks (PB_RW, PB_GWr, PB_GWb, PB_BW), the sub-pixel blocks (PB_RW, PB_GWr, PB_GWb, PB_BW) may be arranged in a Bayer pattern. In addition, when the pixel array 100 is viewed as a whole, the white color filters may be disposed between the red color filters, the green color filters, and the blue color filters so that the red color filters, the green color filters, and the blue color filters are not adjacent to each other. In some implementations, the red color filters, the green color filters, and the blue color filters are alternately arranged with a gap between adjacent red, green and blue color filters, and each white color filter is arranged at the gap.

A grid structure 140 may be disposed between the color filters. The grid structure 140 may include metal as a light absorption layer. For example, the grid structure 140 may include tungsten (W).

In these color filters, the white color filter may have a lower height than the grid structure 140. For example, whereas the red color filters, the green color filters, and the blue color filters are formed to have a higher height than the grid structure 140, each of the white color filters may be formed to have a lower height than the grid structure 140.

FIG. 3 is a cross-sectional view illustrating an example of the pixel array 100 taken along the line A-A′ shown in FIG. 2 based on some implementations of the disclosed technology.

Referring to FIG. 3, the pixel array 100 may include a substrate layer 110, an anti-reflection layer 120, a color filter layer 130, a grid structure 140, and a lens layer 150.

The substrate layer 110 may include a substrate 112, a plurality of photoelectric conversion regions 114, and a plurality of device isolation structures 116. The substrate layer 110 may include a first surface and a second surface facing away from or opposite to the first surface. In this case, the first surface may refer to a light receiving surface upon which light is incident from the outside.

The substrate 112 may include a semiconductor substrate including a monocrystalline silicon material. The substrate 112 may include P-type impurities.

The photoelectric conversion regions 114 may be formed in the semiconductor substrate 112 and each photoelectric conversion region 114 can correspond to a unit pixel. The photoelectric conversion regions 114 may convert (photoelectric conversion) incident light (e.g., visible light) filtered by the color filter layer 130 into photocharge that can carry information corresponding to images in the incident light. Each of the photoelectric conversion regions 114 may include N-type impurities.

Each of the device isolation structures 116 may be formed between photoelectric conversion regions 114 of the adjacent unit pixels within the substrate 112 to isolate the photoelectric conversion regions 114 from each other. The device isolation structure 116 may include a trench structure such as a Back Deep Trench Isolation (BDTI) structure or a Front Deep Trench Isolation (FDTI) structure. Alternatively, the device isolation structure 116 may include a junction isolation structure formed by implanting high-density impurities (e.g., P-type impurities) into the substrate 112.

The anti-reflection layer 120 may be disposed over the first surface of the substrate layer 110 to reduce or prevent reflection of light so that light incident upon the first surface of the substrate layer 110 can effectively reach the photoelectric conversion regions 114. For example, the anti-reflection layer 120 may compensate for a difference in refractive index between the color filter layer 130 and the substrate layer 110, and may thus enable light having penetrated the color filter layer 130 to be effectively incident upon the substrate layer 110. The anti-reflection layer 120 may include a silicon oxide layer, a silicon nitride layer, a silicon oxynitride layer, or a high-permittivity (high-K) layer (e.g., a hafnium oxide layer or an aluminum oxide layer).

The color filter layer 130 may be disposed over the anti-reflection layer 120, and may include color filters that filter predetermined wavelengths (e.g., visible light) of incident light received through the lens layer 150 and transmit the filtered light to the corresponding photoelectric conversion elements 114. For example, the color filter layer 130 may include a plurality of red color filters 130R, a plurality of green color filters 130G, a plurality of blue color filters 130B, and a plurality of white color filters 130W. Each red color filter 130R may transmit red visible light. Each green color filter 130G may transmit green visible light. Each blue color filter 130B may transmit blue visible light. Each white color pixel 130W may transmit visible light of all colors. The color filters 130R, 130G, 130B, and 130W may be arranged one by one for each unit pixel. The color filters (130R, 130G, 130B, 130W) may be formed over the anti-reflection layer 120 in a region defined by the grid structure 140.

In some implementations, the red color filters 130R, the green color filters 130G, and the blue color filters 130B may have a different height from the white color filters 130W. For example, the red color filters 130R, the green color filters 130G, and the blue color filters 130B have a higher height than the grid structure 140, and each of the white color filters 130W may be formed to have a lower height than the grid structure 140. For example, a top surface of each of the white color filters 130W may be located at a lower height than the top surface of the grid structure 140.

The grid structure 140 may be disposed between the color filters on the first surface of the substrate layer 110 to reduce or prevent crosstalk between the adjacent color filters. The grid structure 140 may be formed to vertically overlap the device isolation structure 116. The grid structure 140 may include a metal layer. For example, the grid structure 140 may include tungsten (W).

The lens layer 150 may include an over-coating layer 152 and a plurality of microlenses 154. The over-coating layer 152 may be formed to cover the color filter layer 130 and the grid structure 140 exposed from the color filter layer 130. The over-coating layer 152 may operate as a planarization layer to eliminate or compensate for a step difference caused by the color filter layer 130. The microlenses 154 may be formed over the over-coating layer 152. Each of the microlenses 154 may be formed in a convex lens shape, and may be formed for each unit pixel. The microlenses 154 may converge incident light, and may transmit the converged light to the corresponding photoelectric conversion elements 114. The over-coating layer 152 and the microlenses 154 may be formed of the same materials.

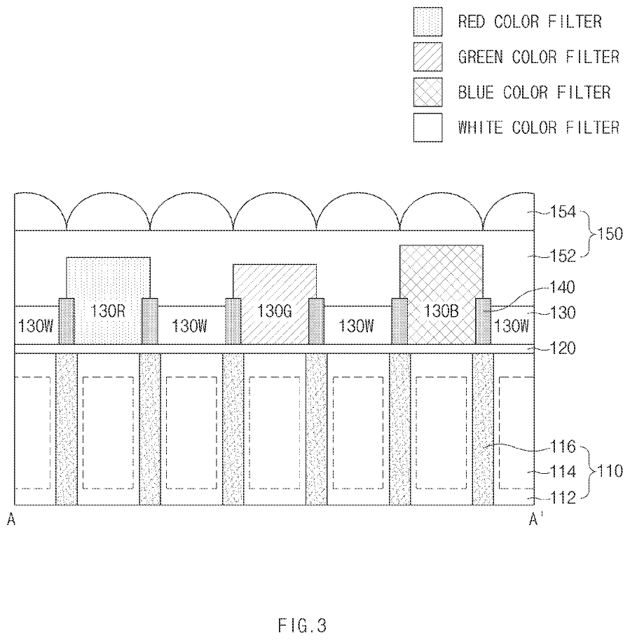

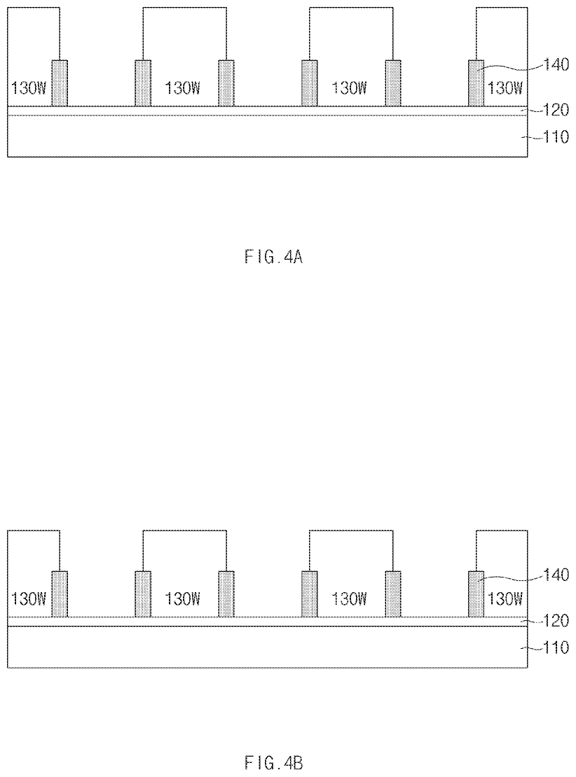

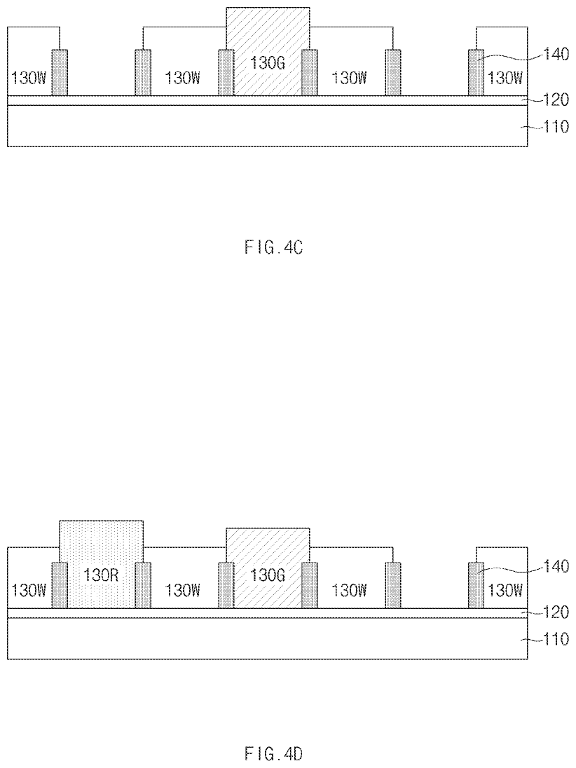

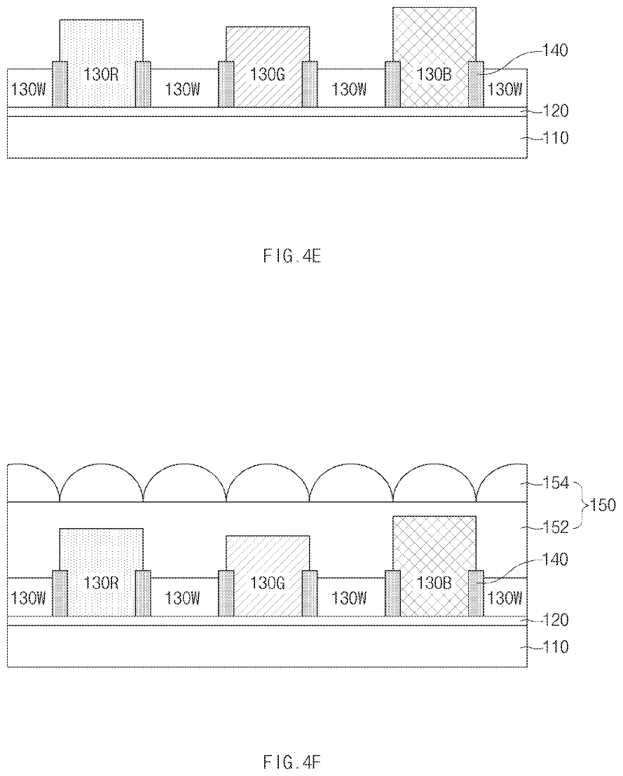

FIGS. 4A to 4F are cross-sectional views illustrating examples of methods for forming the grid structure 140 shown in FIG. 3 based on some implementations of the disclosed technology.

Referring to FIG. 4A, the anti-reflection layer 120 may be formed over the substrate layer 110 that includes photoelectric conversion regions and a device isolation structure. The grid structure 140 may be formed over the anti-reflection layer 120.

For example, after a metal layer is formed over the anti-reflection layer 120, the metal layer may be etched using a mask pattern (etch mask, not shown) defining the region where the grid structure 140 will be formed. In some implementations, the metal layer may include tungsten (W).

Subsequently, after a first color filter material layer is formed to cover the anti-reflection layer 120 and the grid structure 140, the first color filter material layer is patterned to form the white color filters 130W. For example, the first color filter material layer may include a resist material containing no pigment. The first color filter material layer may be patterned through a photolithography process.

The white color filters 130W may be formed in the sub-pixel blocks (PB_RW, PB_GWr, PB_GWb, PB_BW) shown in FIG. 2. In some implementations, since the white color filters 130W occupy the largest portion (50%) of the color filters of the pixel array 100, the white color filters may be formed first.

Referring to FIG. 4B, a surface treatment process may be performed on the white color filters 130W to prevent color mixing by color filters of different colors to be formed in a subsequent process. In some implementations, a descum process can be performed to remove residue remaining after semiconductor fabrication steps discussed above (e.g., photolithography steps). For example, a descum process using nitrogen (N₂) gas may be performed on the white color filters 130W. Through such N₂ descum process, upper portions of the white color filters 130W may be etched and removed.

Referring to FIG. 4C, the green color filters 130G may be formed in some regions between the white color filters 130W. For example, after the second color filter material layer is formed to cover the anti-reflection layer 120, the white color filters 130W, and the grid structure 140, the second color filter material layer is patterned to form the green color filters 130G in some regions between the white color filters 130W.

The green color filters 130G may be formed at positions where the green color filters are formed in the sub-pixel blocks PB_GWr and PB_GWb shown in FIG. 2. The second color filter material layer may include a resist material containing green pigments, and may be patterned through a photolithography process.

Subsequently, the N₂ descum process for surface treatment of the green color filters 130G may be performed. Through this descum process, upper regions of the white color filters 130W may also be partially etched. In addition, as the green color filters 130G are etched, residues (e.g., fine residues) of the green color filters may exist on the top surfaces of the white color filters 130W.

Referring to FIG. 4D, the red color filters 130R may be formed in some regions between the white color filters 130W. For example, after the third color filter material layer is formed to cover the anti-reflection layer 120, the white color filters 130W, the green color filters 130G, and the grid structure 140, the third color filter material layer is patterned so that the red color filters 130R may be formed in some regions between the white color filters 130W.

The red color filters 130R may be formed at positions where the red color filters are formed in the sub-pixel blocks PB_RW of FIG. 2. The third color filter material layer may include a resist material containing red pigments, and may be patterned through a photolithography process.

Subsequently, the N₂ descum process for surface treatment of the red color filters 130R may be performed. Through this descum process, upper regions of the white color filters 130W and upper regions of the green color filters 130G may also be partially etched together. Also, fine residues of the green color filters 130G and fine residues of the red color filters 130R may exist on the top surfaces of the white color filters 130W.

Referring to FIG. 4E, the blue color filters 130B may be formed in some regions between the white color filters 130W. For example, after a fourth color filter material layer is formed to cover the anti-reflection layer 120, the white color filters 130W, the green color filters 130G, the red color filters 130R, and the grid structure 140, the fourth color filter material layer is then patterned so that the blue color filters 130B may be formed in some regions between the white color filters 130W.

The blue color filters 130B may be formed at positions where the blue color filters are formed in the sub-pixel blocks PB_BW of FIG. 2. The fourth color filter material layer may include a resist material containing blue pigments, and may be patterned through a photolithography process.

Subsequently, the nitrogen (N₂) descum process for surface treatment of the blue color filters 130B may be performed. Through this descum process, upper regions of the white color filters 130W, upper regions of the green color filters 130G, and upper regions of the red color filters 130R may also be partially etched together. In this case, fine residues of other color filters may exist on the top surfaces of the white color filters 130W.

Therefore, in some implementations of the disclosed technology, when the descum process is performed on the blue color filters 130B, which is formed after other color filters are formed, the descum process can be performed for a sufficiently long time than the other descum process for other color filters so that all fine residues existing on the top surfaces of the white color filters 130W can be completely removed. For example, as shown in FIG. 4E, the descum process may be performed until the top surfaces of the white color filters 130W become lower than the top surface of the grid structure 140.

Referring to FIG. 4F, a lens layer 150 may be formed to cover the color filters (130R, 130G, 130B, 130W). For example, an over-coating layer 152 may be formed over the color filters (130R, 130G, 130B, 130W) to remove a step difference between the color filters (130R, 130G, 130B, 130W), and microlenses 154 may be formed over the over-coating layer 152.

In some implementations, each of the white color filters 130W may be formed to be significantly thinner than the other color filters 130R, 130G, and 130B, but the over-coating layer 152 is formed relatively thick over each of the white color filters 130W. As such, since the over-coating layer 152 is formed to compensate for such thinning of the white color filters 130W, the white pixels including the white color filters can perform their functions effectively.

Although a structure in which the color filters (R, G, B, W) are arranged as shown in FIG. 2 by way of example, the above-described method can also be used to prevent color mixing with respect to other colors except for the white color when forming the color filters even in other structures each including white color filters.

As is apparent from the above description, the image sensing device based on some implementations of the disclosed technology can effectively prevent other colors from being mixed with white color filters.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a plurality of first color filters configured to transmit light corresponding to a first color;
a plurality of second color filters configured to transmit light corresponding to a second color;
a plurality of third color filters configured to transmit light corresponding to a third color;
a plurality of fourth color filters configured to transmit light corresponding to a fourth color; and
a grid structure disposed between the first to fourth color filters and structured to block light from one color filter to another color filter,
wherein one or more color filters of the first to fourth color filters are formed to have a lower height than the grid structure, and one or more remaining color filters other than the one or more color filters are formed to have a higher height than the grid structure.

2. The image sensing device according to claim 1, wherein:
each of the first color filters is formed to have a lower height than the grid structure, and each of the second to fourth color filters is formed to have a higher height than the grid structure.

3. The image sensing device according to claim 2, wherein:
the second to fourth color filters are formed to have different heights.

4. The image sensing device according to claim 2, wherein:
the first color filters are white color filters.

5. The image sensing device according to claim 4, wherein:
the second color filters are red color filters, the third color filters are green color filters, and the fourth color filters are blue color filters.

6. The image sensing device according to claim 2,
wherein the second to fourth color filters are alternately arranged with a gap between adjacent second to fourth color filters,
wherein each of the first color filters is disposed at the gap between the adjacent second to fourth color filters.

7. The image sensing device according to claim 1, wherein the first to fourth color filters include:
a first group configured to include the plurality of second color filters disposed adjacent to each other in a first diagonal direction and the plurality of first color filters disposed adjacent to each other in a second diagonal direction crossing the first diagonal direction;
a second group and a third group, each of which includes the plurality of third color filters disposed adjacent to each other in the first diagonal direction and the plurality of first color filters disposed adjacent to each other in the second diagonal direction; and
a fourth group configured to include the plurality of fourth color filters disposed adjacent to each other in the first diagonal direction and the plurality of first color filters disposed adjacent to each other in the second diagonal direction.

8. The image sensing device according to claim 7, wherein:
the first to fourth groups are arranged in a Bayer pattern based on the second to fourth colors.

9. The image sensing device according to claim 1, further comprising:
an over-coating layer disposed over the first to fourth color filters,
wherein first regions of the over-coating layer that overlap the first color filters are formed to be thicker than second regions of the over-coating layer that overlap the second to third color filters.

10. A method for manufacturing an image sensing device comprising:
forming a grid structure over a semiconductor substrate; and
sequentially forming first, second, third, and fourth color filters, configured to transmit light corresponding to light of first, second, third, and fourth colors, respectively, in different spaces from among spaces defined by the grid structure,
wherein one or more color filters of the first to fourth color filters are formed to have a lower height than the grid structure, and one or more remaining color filters other than the one or more color filters are formed to have a higher height than the grid structure.

11. The method according to claim 10, wherein:
the first color filters are formed to have a lower height than the grid structure, and the second to fourth color filters are formed to have a higher height than the grid structure.

12. The method according to claim 11, wherein:
the first color filters are white color filters.

13. The method according to claim 12, wherein:
the second color filters are red color filters, the third color filters are green color filters, and the fourth color filters are blue color filters.

14. The method according to claim 10, further comprising:
forming an over-coating layer over the first to fourth color filters.

15. The method according to claim 10, wherein the sequentially forming the first to fourth color filters further includes:
performing a descum process on each of the first to fourth color filters.

16. The method according to claim 15, wherein:
the descum process for the fourth color filters is performed for a longer time than the descum process for the first to third color filters.

17. The method according to claim 16, wherein:
the descum process for the fourth color filters is performed until each of the first color filters has a lower height than the grid structure.

18. The method according to claim 15, wherein:
the descum process is performed using nitrogen (N₂) gas.

19. The method according to claim 10, wherein the sequentially forming the first to fourth color filters includes:
sequentially forming white color filters, green color filters, red color filters, and blue color filters.
